(19) United States
(12) Patent Application Publication
(10) Pub. No.: US 2025/0194159 A1
(43) Pub. Date: Jun. 12, 2025

(54) STRUCTURE HAVING MULTI-DIELECTRIC LAYERS

(71) Applicant: MIKRO MESA TECHNOLOGY CO., LTD., APIA (WS)

(72) Inventors: Li-Yi CHEN, Tainan City (TW); Hsiao-Fu LU, Tainan City (TW)

(21) Appl. No.: 18/530,211

(22) Filed: Dec. 6, 2023

(51) Int. Cl. H01L 29/49; H01L 29/417; H01L 29/423; H01L 29/786; H01L 29/861

(52) U.S. Cl. CPC H10D 30/6739; H10D 30/6729; H10D 30/673; H10D 30/6757; H10D 64/258; H10D 64/671; H10D 8/00; H10D 30/6736

(57) ABSTRACT

A structure having multi-dielectric layers includes a conduction channel, a sidewall oxide dielectric structure, and a top oxide dielectric structure. The conduction channel contains aluminum. The sidewall oxide dielectric structure is in contact with a side surface of the conduction channel and has a first effective permittivity. The top oxide dielectric structure is in contact with a top surface of the conduction channel and a top surface of the sidewall oxide dielectric structure and has a second effective permittivity. A material of the top oxide dielectric structure includes silicon. The first effective permittivity is greater than the second effective permittivity.

### BACKGROUND

### Field of Invention

The present disclosure relates to a structure having multi-dielectric layers.

### Description of Related Art

The statements in this section merely provide background information related to the present disclosure and do not necessarily constitute prior art.

Traditional display manufacturing is a standardized process set. In recent years, there are more and more new types of displays such as a micro light-emitting diode display, a mini light-emitting diode display, and a quantum dot light-emitting diode display . . , etc., which are promising to dominate the future display market, and thus new display manufacturing processes are waiting to be set up. There are many steps contained in a manufacturing process set in order to produce one display, and reducing one of the steps thereof can reduce the cost and enhance the efficiency.

### SUMMARY

According to some embodiments of the present disclosure, a structure having multi-dielectric layers includes a conduction channel, a sidewall oxide dielectric structure, and a top oxide dielectric structure. The conduction channel contains aluminum. The sidewall oxide dielectric structure is in contact with a side surface of the conduction channel and has a first effective permittivity. The top oxide dielectric structure is in contact with a top surface of the conduction channel and a top surface of the sidewall oxide dielectric structure and has a second effective permittivity. A material of the top oxide dielectric structure includes silicon. The first effective permittivity is greater than the second effective permittivity.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a schematic cross-sectional view of an intermediate stage of a method of manufacturing a structure having multi-dielectric layers according to some embodiments of the present disclosure;

FIG. 1B is a schematic cross-sectional view of an intermediate stage of the method of manufacturing a structure having multi-dielectric layers according to some embodiments of the present disclosure;

FIG. 1C is a schematic cross-sectional view of an intermediate stage of the method of manufacturing a structure having multi-dielectric layers according to some embodiments of the present disclosure;

FIG. 2A is a schematic cross-sectional view of a structure having multi-dielectric layers according to some embodiments of the present disclosure;

FIG. 2B is a schematic cross-sectional view of a structure having multi-dielectric layers according to some embodiments of the present disclosure;

FIG. 3A is a schematic cross-sectional view of an intermediate stage of a method of manufacturing a structure having multi-dielectric layers according to some embodiments of the present disclosure;

FIG. 3B is a schematic cross-sectional view of an intermediate stage of a method of manufacturing a structure having multi-dielectric layers according to some embodiments of the present disclosure;

FIG. 4 is a schematic top view of a structure having multi-dielectric layers according to some embodiments of the present disclosure;

FIG. 5 is a schematic cross-sectional view of the structure in FIG. 4 taken along line 5-5 according to some embodiments of the present disclosure;

FIG. 6 is a schematic cross-sectional view of the structure in FIG. 4 taken along line 6-6 according to some embodiments of the present disclosure;

FIG. 7 is a schematic top view of a structure having multi-dielectric layers according to some embodiments of the present disclosure;

FIG. 8 is a schematic cross-sectional view of a structure having multi-dielectric layers according to some embodiments of the present disclosure;

FIG. 9 is a schematic cross-sectional view of a structure having multi-dielectric layers according to some embodiments of the present disclosure; and

FIG. 10 is a schematic cross-sectional view of a structure having multi-dielectric layers according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “according to some embodiments” or the like in various places throughout this specification are not necessarily referring to the same embodiment of the disclosure. Furthermore, the particular features, structures, configurations, or characteristics may be combined in any suitable manner in one or more embodiments.

The terms “micro” device, “micro” p-n diode or “micro” LED as used herein may refer to the descriptive size of certain devices or structures according to embodiments of the present disclosure. As used herein, the terms “micro” devices or structures may be meant to refer to the scale of 1 to 100 μm. However, it is to be appreciated that embodiments of the present disclosure are not necessarily so limited, and that certain aspects of the embodiments may be applicable to larger, and possibly smaller size scales. The refractive index mentioned in the following, unless otherwise specified, is based on the refractive index of light with a wavelength λ of 550 nm.

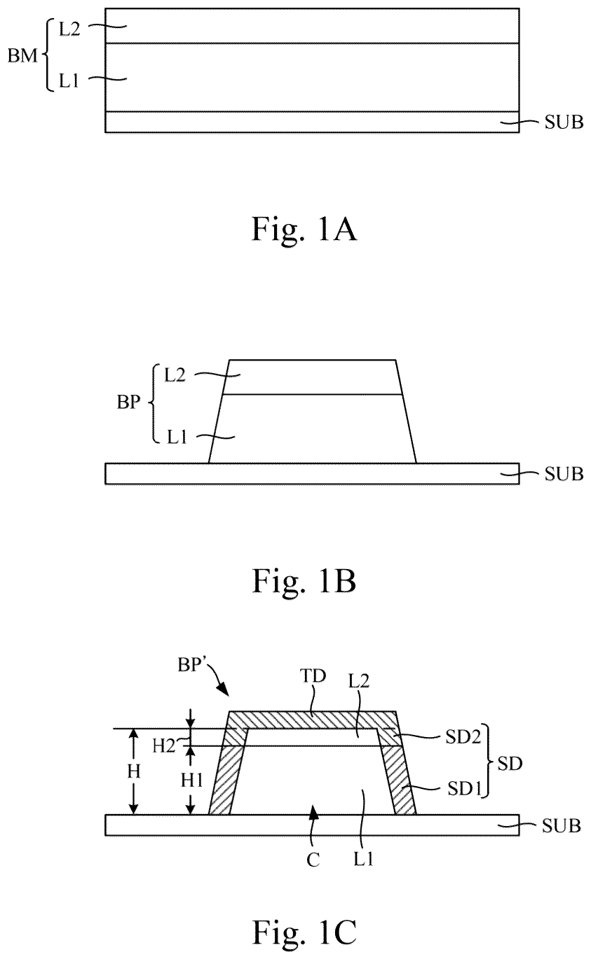

Reference is made to FIG. 1A. FIG. 1A is a schematic cross-sectional view of an intermediate stage of a method of manufacturing a structure having multi-dielectric layers according to some embodiments of the present disclosure. As shown in FIG. 1A, a first metal layer L1 is deposited on a substrate SUB, and a second metal layer L2 is deposited on the first metal layer L1.

Reference is made to FIG. 1B. FIG. 1B is a schematic cross-sectional view of an intermediate stage of the method of manufacturing a structure having multi-dielectric layers according to some embodiments of the present disclosure. The intermediate stage shown in FIG. 1A may be sequentially followed by the intermediate stage shown in FIG. 1B. As shown in FIG. 1B, the first metal layer L1 and the second metal layer L2 is etched to form a bottom metal pattern BP. For example, to form the bottom metal pattern BP, a patterned photoresist (not shown) may be deposited on the second metal layer L2, and then the first metal layer L1 and the second metal layer L2 are etched through the patterned photoresist. After the bottom metal pattern BP is formed, the patterned photoresist may be at least partially removed.

Reference is made to FIG. 1C. FIG. 1C is a schematic cross-sectional view of an intermediate stage of the method of manufacturing a structure having multi-dielectric layers according to some embodiments of the present disclosure. The intermediate stage shown in FIG. 1B may be sequentially followed by the intermediate stage shown in FIG. 1C. As shown in FIG. 1C, an anodization process is performed to partially anodize the bottom metal pattern BP. Specifically, the bottom metal pattern BP is anodized from the outer surface thereof, such that the anodized bottom metal pattern BP′ includes a conduction channel C, a sidewall oxide dielectric structure SD, and a top oxide dielectric structure TD. The sidewall oxide dielectric structure SD is in contact with a side surface of the conduction channel C. The top oxide dielectric structure TD is in contact with a top surface of the conduction channel C and a top surface of the sidewall oxide dielectric structure SD. In some embodiments, the sidewall oxide dielectric structure SD may be defined by the anodized part of the anodized bottom metal pattern BP′ below the top surface of the conduction channel C, and the top oxide dielectric structure TD may be defined by the anodized part of the anodized bottom metal pattern BP′ above the top surface of the conduction channel C.

In the present embodiment, as shown in FIG. 1C, both of the first metal layer L1 and the second metal layer L2 are partially anodized. Specifically, the sidewall oxide dielectric structure SD includes a first metal oxide segment SD1 and a second metal oxide segment SD2 connected to each other. The first metal oxide segment SD1 is the anodized part of the first metal layer L1, and the second metal oxide segment SD2 is the anodized part of the second metal layer L2. The first metal oxide segment SD1 is in contact with a side surface of the unanodized part of the first metal layer L1. The second metal oxide segment SD2 is in contact with a side surface of the unanodized part of the second metal layer L2. In other words, the conduction channel C is a multilayer structure formed by the unanodized part of the first metal layer L1 and the unanodized part of the second metal layer L2. The top oxide dielectric structure TD only has a single metal oxide layer and is further connected to the second metal oxide segment SD2. It can be seen that a sum of a segment number of the metal oxide segments of the sidewall oxide dielectric structure SD and a layer number of the metal oxide layer of the top oxide dielectric structure TD is equal to three.

In some other embodiments, the sum of the segment number of the metal oxide segment(s) of the sidewall oxide dielectric structure SD and a layer number of the metal oxide layer(s) of the top oxide dielectric structure TD may be greater than three.

In some embodiments, the conduction channel C contains aluminum. In this way, the conduction channel C has the function of electrical conduction compared with the sidewall oxide dielectric structure SD and the top oxide dielectric structure TD. In some embodiments, an atomic ratio of aluminum in the conduction channel C is greater than 50%.

In some embodiments, in addition to aluminum, the first metal layer L1 may further contain rare earth metal, such as Nd or Ce. In this way, the first metal layer L1 can reduce hillock of aluminum in the subsequent processes.

In some embodiments, the second metal layer L2 may contain molybdenum. In this way, the second metal layer L2 can prevent the first metal layer L1 which contains aluminum from occurring hillock in the subsequent high temperature process.

In some embodiments, a material of the top oxide dielectric structure TD includes silicon, the sidewall oxide dielectric structure SD has a first effective permittivity, and the top oxide dielectric structure TD has a second effective permittivity. In some embodiments, a material of the top oxide dielectric structure TD includes silicon, such that the first effective permittivity is greater than the second effective permittivity. In addition, since the top oxide dielectric structure TD includes silicon, the top oxide dielectric structure TD covering the conduction channel C can be stronger and more stable. Since the top oxide dielectric structure TD only has a single metal oxide layer, the second effective permittivity is just the permittivity of the top oxide dielectric structure TD. In some embodiments where the sidewall oxide dielectric structure SD includes a plurality of metal oxide segments (i.e., the first metal oxide segment SD1 and the second metal oxide segment SD2), the first effective permittivity of the sidewall oxide dielectric structure SD may be obtained by using the following formula (1).

$${ϵ}_{SD} = \frac{{ϵ}_{SD 1} \times H 1 + {ϵ}_{SD 2} \times H 2}{H} \qquad ( 1 )$$

In the formula (1), EsD represents the first effective permittivity of the sidewall oxide dielectric structure SD, EsD1 represents the permittivity of the first metal oxide segment SD1, ESD2 represents the permittivity of second metal oxide segment SD2, H1 represents the height of the first metal oxide segment SD1 relative to the substrate SUB, H2 represents the height of the second metal oxide segment SD2 relative to the substrate SUB, and H represents the height of an entirety of the sidewall oxide dielectric structure SD.

In some embodiments where the sidewall oxide dielectric structure SD includes more than two metal oxide segments, the first effective permittivity of the sidewall oxide dielectric structure SD may be obtained by using the following formula (2).

$${ϵ}_{SD} = \frac{{ϵ}_{SD 1} \times H 1 + {ϵ}_{SD 2} \times H 2 + … + {ϵ}_{{SD}_{m}} \times Hm}{H} \qquad ( 1 )$$

In the formula (2), m is an integer greater than two, EsDm represents the permittivity of the m-th metal oxide segment of the sidewall oxide dielectric structure SD, and Hm represents the height of the m-th metal oxide segment relative to the substrate SUB.

In some embodiments, the permittivities ESD1 to ESDm and the second effective permittivity of the top oxide dielectric structure TD may be measured by using a low frequency such as 1 KHz, but the present disclosure is not limited in this regard.

In some embodiments, a metal composition of the sidewall oxide dielectric structure SD and a metal composition of the top oxide dielectric structure TD are different. For example, the metal composition of the sidewall oxide dielectric structure SD may include aluminum, and the metal composition of the top oxide dielectric structure TD may include aluminum and zirconium.

In some embodiments, a material of the top oxide dielectric structure TD includes rare earth metal.

In some embodiments, a material of the top oxide dielectric structure TD includes at least one of hafnium, tantalum, zirconium, titanium, and tungsten.

In some embodiments, the top oxide dielectric structure TD includes aluminum, magnesium, strontium, magnesium, calcium strontium, or scandium.

In some embodiments, a thickness of a combination of the conduction channel C and the top oxide dielectric structure TD is smaller than 10 μm. As mentioned above, the sidewall oxide dielectric structure SD may be defined by the anodized part of the anodized bottom metal pattern BP′ below the top surface of the conduction channel C, and the top oxide dielectric structure TD may be defined by the anodized part of the anodized bottom metal pattern BP′ above the top surface of the conduction channel C. In this regard, the thickness of the conduction channel C is equal to the height H of the sidewall oxide dielectric structure SD relative to the substrate SUB.

In some embodiments, the thickness of the conduction channel C is equal to or greater than 1/10 of the thickness of the combination of the conduction channel C and the top oxide dielectric structure TD. In this way, the resistance of the anodized bottom metal pattern BP′ will not be too large.

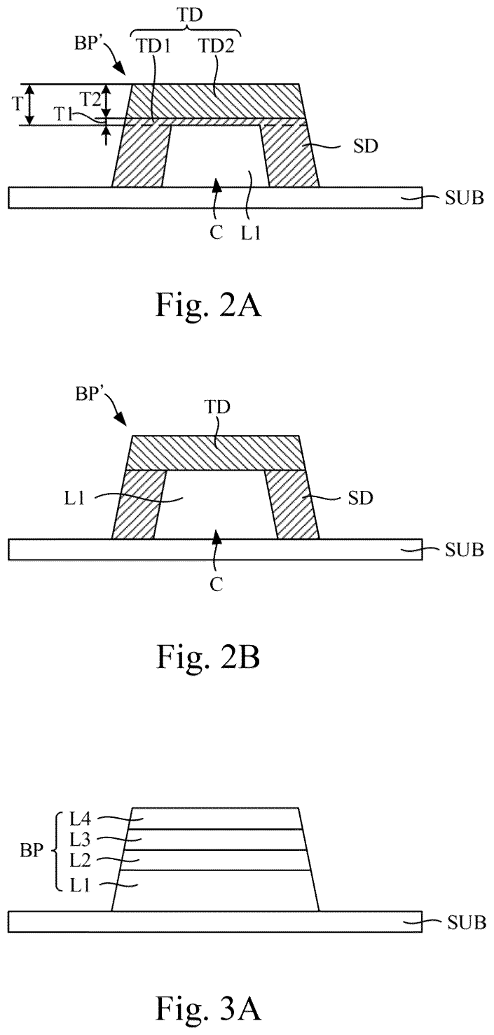

Reference is made to FIG. 2A. FIG. 2A is a schematic cross-sectional view of a structure having multi-dielectric layers according to some embodiments of the present disclosure. As shown in FIG. 2A, the first metal layer L1 is partially anodized, and the second metal layer L2 is entirely anodized. Specifically, the top oxide dielectric structure includes a first metal oxide layer TD1 and a second metal oxide layer TD2 connected to each other. The first metal oxide layer TD1 is the anodized part of the first metal layer L1, and the second metal oxide layer TD2 is the anodized part of the second metal layer L2. The first metal oxide layer TD1 is in contact with a top surface of the unanodized part of the first metal layer L1. The sidewall oxide dielectric structure SD only has a single metal oxide segment, and the first metal oxide layer TD1 is further connected to the sidewall oxide dielectric structure SD. It can be seen that a sum of a segment number of the metal oxide segment of the sidewall oxide dielectric structure SD and a layer number of the metal oxide layers of the top oxide dielectric structure TD is equal to three.

In some embodiments, a material of the top oxide dielectric structure TD includes silicon, the sidewall oxide dielectric structure SD has a first effective permittivity, and the top oxide dielectric structure TD has a second effective permittivity. In some embodiments, a material of the top oxide dielectric structure TD includes silicon, such that the first effective permittivity is greater than the second effective permittivity. Since the sidewall oxide dielectric structure SD only has a single metal oxide segment, the first effective permittivity is just the permittivity of the sidewall oxide dielectric structure SD. In some embodiments where the top oxide dielectric structure TD includes a plurality of metal oxide layers (i.e., the first metal oxide layer TD1 and the second metal oxide layer TD2), the second effective permittivity of the top oxide dielectric structure TD may be obtained by using the following formula (3).

$$\frac{T}{{ϵ}_{TD}} = \frac{T 1}{{ϵ}_{{TD}_{1}}} + \frac{T 2}{{ϵ}_{{TD}_{2}}} \qquad ( 3 )$$

In the formula (3), ε_{TD} represents the second effective permittivity of the top oxide dielectric structure TD, ε_{TD1} represents the permittivity of the first metal oxide layer TD1, ε_{TD2} represents the permittivity of second metal oxide layer TD2, T1 represents the thickness of the first metal oxide layer TD1, T2 represents the thickness of the second metal oxide layer TD2, and T represents the thickness of an entirety of the top oxide dielectric structure TD.

In some embodiments where the top oxide dielectric structure TD includes more than two metal oxide layers, the second effective permittivity of the top oxide dielectric structure TD may be obtained by using the following formula (4).

$$\frac{T}{{ϵ}_{TD}} = \frac{T 1}{{ϵ}_{{TD}_{1}}} + \frac{T 2}{{ϵ}_{{TD}_{2}}} + … + \frac{Tn}{{ϵ}_{TDn}} \qquad ( 4 )$$

In the formula (4), n is an integer greater than two, εTDn represents the permittivity of the n-th metal oxide layer of the top oxide dielectric structure TD, and Tn represents the thickness of the n-th metal oxide layer.

In some embodiments, the permittivities ε_{TD1} to εTDn and the first effective permittivity of the sidewall oxide dielectric structure SD may be measured by using a low frequency such as 1 KHz, but the present disclosure is not limited in this regard.

It should be pointed out that the formula (4) for calculating the second effective permittivity is obtained from the formula for calculating the capacitance of series connection of parallel plate capacitors. The formula for calculating the capacitance is C=ε×A/d, where C is the value of the capacitance, A is the area of each plate, d is the distance between the plates, and e is the permittivity of the material between the plates of the parallel capacitor.

In some embodiments, the layer number of the metal oxide layers of the top oxide dielectric structure TD is equal to two, such as the structure shown in FIG. 2A, but the present disclosure is not limited in this regard.

In some other embodiments, the layer number of the metal oxide layers of the top oxide dielectric structure TD may be greater than two. To manufacture the structure, an additional metal layer may be deposited on the second metal layer L2 after the intermediate stage of FIG. 1B and before the intermediate stage of FIG. 1C.

Reference is made to FIG. 2B. FIG. 2B is a schematic cross-sectional view of a structure having multi-dielectric layers according to some embodiments of the present disclosure. As shown in FIG. 2B, the first metal layer L1 is partially anodized, and the second metal layer L2 is entirely anodized. Specifically, the sidewall oxide dielectric structure SD only has a single metal oxide segment, and the top oxide dielectric structure TD only has a single metal oxide layer. The sidewall oxide dielectric structure SD is the anodized part of the first metal layer L1. The top oxide dielectric structure TD is the anodized part of the second metal layer L2. It can be seen that a sum of a segment number of the metal oxide segment of the sidewall oxide dielectric structure SD and a layer number of the metal oxide layer of the top oxide dielectric structure TD is equal to two.

In some embodiments, the sidewall oxide dielectric structure SD has a first effective permittivity, the top oxide dielectric structure TD has a second effective permittivity, and the first effective permittivity is greater than the second effective permittivity. As shown in FIG. 2B, since the sidewall oxide dielectric structure SD only has a single metal oxide segment, the first effective permittivity is just the permittivity of the sidewall oxide dielectric structure SD. Since the top oxide dielectric structure TD only has a single metal oxide layer, the second effective permittivity is just the permittivity of the top oxide dielectric structure TD.

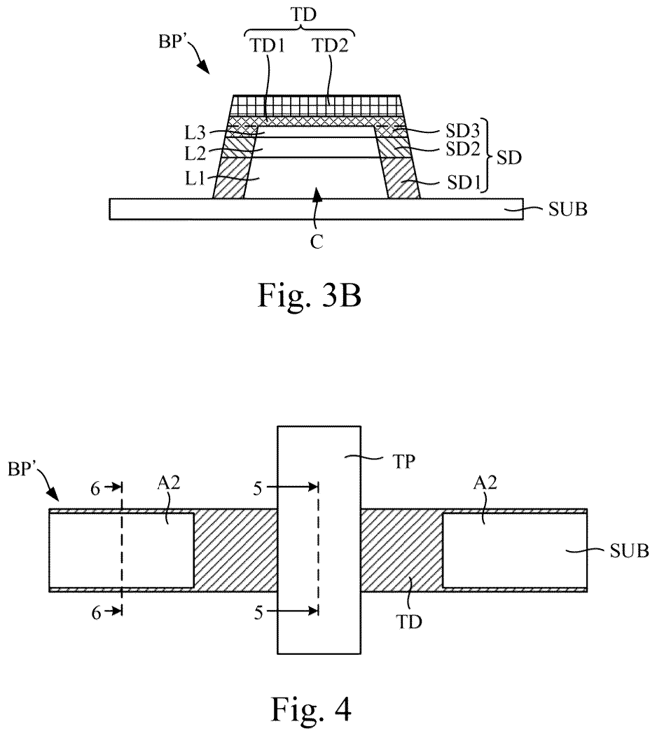

Reference is made to FIG. 3A. FIG. 3A is a schematic cross-sectional view of an intermediate stage of a method of manufacturing a structure having multi-dielectric layers according to some embodiments of the present disclosure. As shown in FIG. 3A, the bottom metal pattern BP includes a first metal layer L1, a second metal layer L2 deposited on the first metal layer L1, a third metal layer L3 deposited on the second metal layer L2, and a fourth metal layer L4 deposited on the third metal layer L3. The intermediate stage shown in FIG. 3A corresponds to the intermediate stage shown in FIG. 1B.

Reference is made to FIG. 3B. FIG. 3B is a schematic cross-sectional view of an intermediate stage of a method of manufacturing a structure having multi-dielectric layers according to some embodiments of the present disclosure. The intermediate stage shown in FIG. 3A may be sequentially followed by the intermediate stage shown in FIG. 3B, and the intermediate stage shown in FIG. 3B corresponds to the intermediate stage shown in FIG. 1C. As shown in FIG. 3B, an anodization process is performed to partially anodize the bottom metal pattern BP, such that the anodized bottom metal pattern BP′ includes a conduction channel C, a sidewall oxide dielectric structure SD, and a top oxide dielectric structure TD. The sidewall oxide dielectric structure SD is in contact with a side surface of the conduction channel C. The top oxide dielectric structure TD is in contact with a top surface of the conduction channel C and a top surface of the sidewall oxide dielectric structure SD.

Specifically, the first metal layer L1, the second metal layer L2, and the third metal layer L3 are partially anodized, and the fourth metal layer L4 is entirely anodized. The sidewall oxide dielectric structure SD includes a first metal oxide segment SD1, a second metal oxide segment SD2, and a third metal oxide segment SD3 sequentially connected. The first metal oxide segment SD1 is the anodized part of the first metal layer L1, the second metal oxide segment SD2 is the anodized part of the second metal layer L2, and the third metal oxide segment SD3 is the anodized part of the third metal layer L3 below the top surface of the conduction channel C. The first metal oxide segment SD1 is in contact with a side surface of the unanodized part of the first metal layer L1. The second metal oxide segment SD2 is in contact with a side surface of the unanodized part of the second metal layer L2. The third metal oxide segment SD3 is in contact with a side surface of the unanodized part of the third metal layer L3. In other words, the conduction channel C is a multilayer structure formed by the unanodized part of the first metal layer L1, the unanodized part of the second metal layer L2, and the unanodized part of the third metal layer L3 below the top surface of the conduction channel C. The top oxide dielectric structure TD includes a first metal oxide layer TD1 and a second metal oxide layer TD2 connected to each other. The first metal oxide layer TD1 is the anodized part of the third metal layer L3 above the top surface of the conduction channel C, and the second metal oxide layer TD2 is the anodized fourth metal layer L4. The first metal oxide layer TD1 is in contact with a top surface of the unanodized part of the third metal layer L3. The second metal oxide layer TD2 is in contact with a top surface of the first metal oxide layer TD1. It can be seen that a sum of a segment number of the metal oxide segments of the sidewall oxide dielectric structure SD and a layer number of the metal oxide layer of the top oxide dielectric structure TD is equal to five.

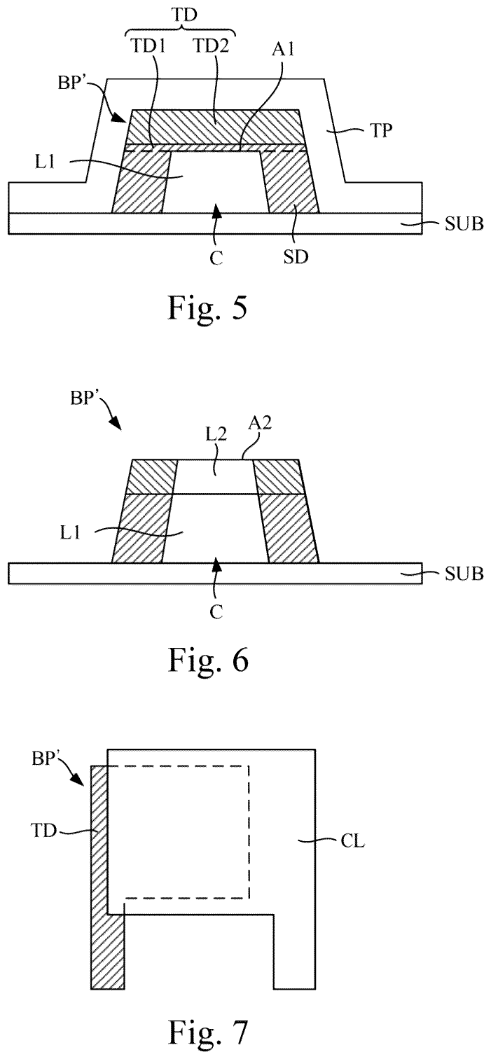

Reference is made to FIGS. 4, 5, and 6. FIG. 4 is a schematic top view of a structure having multi-dielectric layers according to some embodiments of the present disclosure. FIG. 5 is a schematic cross-sectional view of the structure in FIG. 4 taken along line 5-5 according to some embodiments of the present disclosure. FIG. 6 is a schematic cross-sectional view of the structure in FIG. 4 taken along line 6-6 according to some embodiments of the present disclosure. As shown in FIGS. 4 and 5, the structure having multi-dielectric layers further includes a top conductive pattern TP. The top conductive pattern TP crosses the conduction channel C through the top oxide dielectric structure TD. In this way, the top conductive pattern TP and the anodized bottom metal pattern BP′ form a cross over structure.

As shown in FIGS. 4, 5, and 6, the top surface of the conduction channel C has a covered section A1 covered by the top oxide dielectric structure TD and two uncovered sections A2 exposed by the top oxide dielectric structure TD. In some embodiments, the two uncovered sections A2 may be respectively in contact with two conductive patterns other than the top conductive pattern TP. In this way, the two conductive patterns respectively located at opposite sides of the top conductive pattern TP may be electrically connected to each other via the conduction channel C of the anodized bottom metal pattern BP′.

In some embodiments, to form the two uncovered sections A2, the patterned photoresist deposited on the bottom metal pattern BP after the intermediate stage of FIG. 1B may partially cover the top surface of the second metal layer L2. In this way, in the intermediate stage of FIG. 1C, portions of the top surface of the second metal layer L2 covered and in contact with the patterned photoresist form the uncovered sections A2 of the conduction channel C, and the portion of the top surface of the second metal layer L2 not covered by the patterned photoresist form the covered section A1 of the conduction channel C.

Reference is made to FIG. 7. FIG. 7 is a schematic top view of a structure having multi-dielectric layers according to some embodiments of the present disclosure. As shown in FIG. 7, the structure having multi-dielectric layers further includes a conductor layer CL. The conductor layer CL covers the anodized bottom metal pattern BP′. Specifically, the conductor layer CL covers on the top oxide dielectric structure TD of the anodized bottom metal pattern BP′. In this way, the conductor layer CL forms a capacitor with the conduction channel C in the anodized bottom metal pattern BP′ and under the top oxide dielectric structure TD. For example, a cross section of the combination of the conductor layer CL and the anodized bottom metal pattern BP′ may be similar to the cross section shown in FIG. 5.

In some embodiments, the combination of the conductor layer CL and the anodized bottom metal pattern BP′ shown in FIG. 7 may form a thin-film diode when the top oxide dielectric structure TD is thin enough. In general, the larger the voltage difference between the conductor layer CL and the conduction channel C, the easier the current tunneling effect occurs.

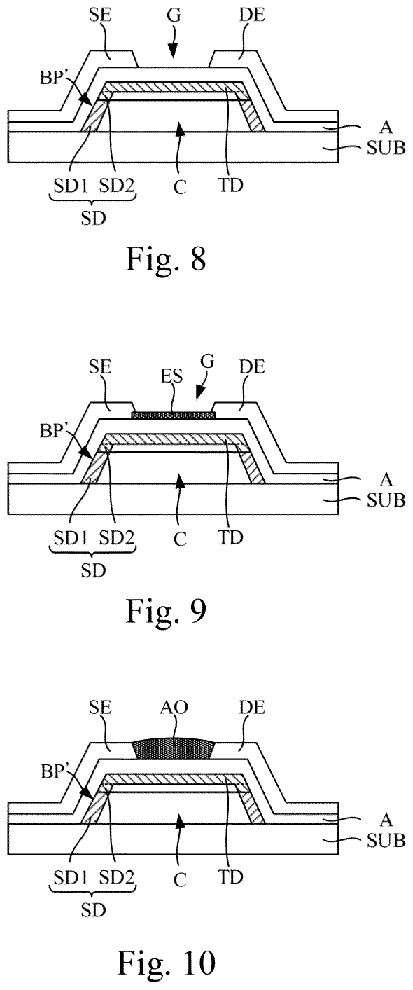

Reference is made to FIG. 8. FIG. 8 is a schematic cross-sectional view of a structure having multi-dielectric layers according to some embodiments of the present disclosure. As shown in FIG. 8, in addition to the anodized bottom metal pattern BP′, the structure having multi-dielectric layers further includes a semiconductor layer A, a source electrode SE, and a drain electrode DE. The semiconductor layer A covers the sidewall oxide dielectric structure SD and the top oxide dielectric structure TD of the anodized bottom metal pattern BP′. The source electrode SE covers the semiconductor layer A. The drain electrode DE covers the semiconductor layer A and is spaced apart from the source electrode SE by a gap G. The gap G is right above the conduction channel C. In other words, the structure as shown in FIG. 8 is a thin-film transistor. The structure as shown in FIG. 8 may be manufactured by using a back-channel-etch (BCE) process, which will not be described in detail.

Reference is made to FIG. 9. FIG. 9 is a schematic cross-sectional view of a structure having multi-dielectric layers according to some embodiments of the present disclosure. As shown in FIG. 9, in addition to the anodized bottom metal pattern BP′, the structure having multi-dielectric layers further includes a semiconductor layer A, an etching stopper ES, a source electrode SE, and a drain electrode DE. The semiconductor layer A covers the sidewall oxide dielectric structure SD and the top oxide dielectric structure TD of the anodized bottom metal pattern BP′. The etching stopper ES is disposed on the semiconductor layer A and right above the conduction channel C. The source electrode SE covers the semiconductor layer A and the etching stopper ES. The drain electrode DE covers the semiconductor layer A and the etching stopper ES and is spaced apart from the source electrode SE by a gap G on the etching stopper ES. In other words, the structure as shown in FIG. 9 is also a thin-film transistor. The structure as shown in FIG. 9 may be manufactured by using an etch-stop-layer (ESL) process, which will not be described in detail.

Reference is made to FIG. 10. FIG. 10 is a schematic cross-sectional view of a structure having multi-dielectric layers according to some embodiments of the present disclosure. As shown in FIG. 10, in addition to the anodized bottom metal pattern BP′, the structure having multi-dielectric layers further includes a semiconductor layer A and a metal pattern covering the semiconductor layer A. The semiconductor layer A covers the sidewall oxide dielectric structure SD and the top oxide dielectric structure TD of the anodized bottom metal pattern BP′. The metal pattern includes an anodic oxide segment AO and two conductive segments electrically isolated from each other by the anodic oxide segment AO. The anodic oxide segment AO is right above the conduction channel C. The two conductive segments of the metal pattern respectively serve as a source electrode SE and a drain electrode DE. In other words, the structure as shown in FIG. 10 is also a thin-film transistor. The structure as shown in FIG. 10 may be manufactured by depositing the semiconductor layer A to cover the anodized bottom metal pattern BP′, forming the metal pattern to cover the semiconductor layer A, and anodizing the metal pattern to form the anodic oxide segment AO which reaches the semiconductor layer A and separates the source electrode SE and the drain electrode DE. In some embodiments, the metal pattern contains aluminum, such that the source electrode SE and the drain electrode DE also contain aluminum.

In some embodiments, the top oxide dielectric structure TD of the anodized bottom metal pattern BP′ includes an amorphous phase layer. For example, as shown in FIG. 2A, the top oxide dielectric structure TD of the anodized bottom metal pattern BP′ is a multilayer structure, and the amorphous phase layer is a topmost layer (i.e., the second metal oxide layer TD2) of the top oxide dielectric structure TD. Since the amorphous phase layer has no grain boundary, the leakage current is relatively small. In some embodiments, aluminum contained in the top oxide dielectric structure TD keeps the second metal oxide layer TD2 amorphous.

According to the foregoing recitations of the embodiments of the disclosure, it can be seen that in the structure having multi-dielectric layers of the present disclosure, the top oxide dielectric structure includes silicon, such that the first effective permittivity of the sidewall oxide dielectric structure in contact with the side surface of the conduction channel is greater than the second effective permittivity of the top oxide dielectric structure in contact with the top surface of the conduction channel. In addition, since the top oxide dielectric structure includes silicon, the top oxide dielectric structure covering the conduction channel can be stronger and more stable. Moreover, when the structure having multi-dielectric layers of the present disclosure is applied to a thin-film transistor, the top oxide dielectric structure may include more combinations of oxide layers. Different kinds of metal alloy oxide (e.g., Al₂O₃, ZrO₂, or mixture of them) can be chosen to benefit the quality of interface between the top oxide dielectric structure and the semiconductor layer while still keeping good conductivity in the conduction channel. When the structure having multi-dielectric layers of the present disclosure is applied to a cross over structure, the cross over structure will have low overlap capacitance, which can reduce RC delay.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A structure having multi-dielectric layers, comprising:
a conduction channel containing aluminum;
a sidewall oxide dielectric structure in contact with a side surface of the conduction channel and having a first effective permittivity; and
a top oxide dielectric structure in contact with a top surface of the conduction channel and a top surface of the sidewall oxide dielectric structure and having a second effective permittivity, wherein a material of the top oxide dielectric structure comprises silicon,
wherein the first effective permittivity is greater than the second effective permittivity.

2. The structure of claim 1, wherein an atomic ratio of aluminum in the conduction channel is greater than 50%.

3. The structure of claim 1, wherein a metal composition of the sidewall oxide dielectric structure and a metal composition of the top oxide dielectric structure are different.

4. The structure of claim 1, wherein the sidewall oxide dielectric structure comprises at least one metal oxide segment, the top oxide dielectric structure comprises at least one metal oxide layer, and a sum of a segment number of the at least one metal oxide segment of the sidewall oxide dielectric structure and a layer number of the at least one metal oxide layer of the top oxide dielectric structure is equal to or greater than three.

5. The structure of claim 1, wherein the material of the top oxide dielectric structure further comprises rare earth metal.

6. The structure of claim 1, wherein the material of the top oxide dielectric structure further comprises at least one of hafnium, tantalum, zirconium, titanium, and tungsten.

7. The structure of claim 1, wherein the material of the top oxide dielectric structure further comprises aluminum, magnesium, strontium, magnesium, calcium strontium, or scandium.

8. The structure of claim 1, wherein a thickness of a combination of the conduction channel and the top oxide dielectric structure is smaller than 10 μm.

9. The structure of claim 1, wherein a thickness of the conduction channel is equal to or greater than 1/10 of a thickness of a combination of the conduction channel and the top oxide dielectric structure.

10. The structure of claim 1, further comprising a conductive pattern crossing the conduction channel through the top oxide dielectric structure.

11. The structure of claim 10, wherein the top surface of the conduction channel has a covered section covered by the top oxide dielectric structure and two uncovered sections exposed by the top oxide dielectric structure.

12. The structure of claim 1, wherein the top surface of the conduction channel has a covered section covered by the top oxide dielectric structure and at least one uncovered section exposed by the top oxide dielectric structure.

13. The structure of claim 1, further comprising:
a semiconductor layer covering the sidewall oxide dielectric structure and the top oxide dielectric structure;
a source electrode covering the semiconductor layer; and
a drain electrode covering the semiconductor layer and spaced apart from the source electrode by a gap,
wherein the gap is right above the conduction channel.

14. The structure of claim 1, further comprising:
a semiconductor layer covering the sidewall oxide dielectric structure and the top oxide dielectric structure; and
a metal pattern covering the semiconductor layer and comprising an anodic oxide segment and two conductive segments electrically isolated from each other by the anodic oxide segment,
wherein the anodic oxide segment is right above the conduction channel.

15. The structure of claim 1, further comprising:
a semiconductor layer covering the sidewall oxide dielectric structure and the top oxide dielectric structure;
an etching stopper disposed on the semiconductor layer and right above the conduction channel;
a source electrode covering the semiconductor layer and the etching stopper; and
a drain electrode covering the semiconductor layer and the etching stopper and spaced apart from the source electrode by a gap on the etching stopper.

16. The structure of claim 1, wherein the conduction channel is a multilayer structure.

17. The structure of claim 1, wherein the top oxide dielectric structure comprises a plurality of metal oxide layers, and a layer number of the metal oxide layers is equal to or greater than two.

18. The structure of claim 1, further comprising:
a conductor layer covering on the top oxide dielectric structure and forming a capacitor with the conduction channel.

19. The structure of claim 1, wherein the top oxide dielectric structure comprises an amorphous phase layer.

20. The structure of claim 19, wherein the top oxide dielectric structure is a multilayer structure, and the amorphous phase layer is a topmost layer of the top oxide dielectric structure.
